(19) United States
(12) Patent Application Publication
(10) Pub. No.: US 2010/0052137 A1
(43) Pub. Date: Mar. 4, 2010

(54) ENHANCED WIRE BOND STABILITY ON REACTIVE METAL SURFACES OF A SEMICONDUCTOR DEVICE BY ENCAPSULATION OF THE BOND STRUCTURE

(76) Inventors: Andreas Meyer, Dresden (DE); Matthias Lehr, Dresden (DE); Frank Kuechenmeister, Dresden (DE)

Correspondence Address: WILLIAMS, MORGAN & AMERSON, 10333 RICHMOND, SUITE 1100, HOUSTON, TX, 77042, US

(21) Appl. No.: 12/490,900

(22) Filed: Jun. 24, 2009

(30) Foreign Application Priority Data
Aug. 29, 2008 (DE) 10 2008 045 033.2

(51) Int. Cl. H01L 23/29; H01L 21/56

(52) U.S. Cl. 257/687; 438/124; 257/690; 257/E21.504; 257/E21.506; 257/E23.121

(57) ABSTRACT

The wire bond structure of sophisticated metallization systems, for instance based on copper, may be provided without a terminal aluminum layer and without any passivation layers for exposed copper surfaces by providing a fill material after the wire bonding process in order to encapsulate at least the sensitive metal surfaces and a portion of the bond wire. Hence, significant cost reduction, reduced cycle times and a reduction of the required process steps may be accomplished independently from the wire bond materials used. Thus, integrated circuits requiring a sophisticated metallization system may be connected by wire bonding to the corresponding package or carrier substrate with a required degree of reliability based on a corresponding fill material for encapsulating at least the sensitive metal surfaces.

### BACKGROUND OF THE INVENTION

1. Field of the Invention

The present disclosure generally relates to the field of integrated circuits, and, more particularly, to a back end of line processing for a wire bonding structure in sophisticated metallization structures, including highly reactive metals, such as copper and the like.

2. Description of the Related Art

The manufacture of integrated circuits involves many complex process steps to form circuit elements, such as transistors, capacitors, resistors and the like, in and above an appropriate semiconductor material. In recent years, enormous advances have been made in increasing integration density and overall functionality of the integrated circuits. These advances have been achieved by scaling the individual circuit elements to dimensions in the deep sub-micrometer range, with currently used critical dimensions, such as the gate length of a field effect transistor, of 30 nm and less. Hence, millions of circuit elements may be provided in a die, wherein a complex interconnect fabric may also have to be designed, in which, typically, each circuit element may be electrically connected to one or more other circuit elements. These interconnect structures are typically established in a metallization system comprising one or more wiring levels, in which appropriate metal features are formed according to the circuit configuration under consideration in a similar manner as a multi-level printed circuit board, wherein, however, the dimensions of the metal features have to adapted to the dimensions of the semiconductor circuit elements, such as the transistors and the like. Over many decades, aluminum has been used as the metal of choice for forming the metal features in the metallization layers of the semiconductor devices due to its moderately high thermal and electrical conductivity, its self-limiting creation of a passivating oxide layer and its compatibility with other materials and process techniques used for fabricating integrated devices. With the continuous reduction of the circuit dimensions, the dimensions of the metal features have resulted in a situation in which the overall signal delay in the devices is no longer restricted by the performance of the individual semiconductor circuit elements, such as the switching speed of the transistors, but is substantially determined by the parasitic time constants in the metallization system caused by the restricted conductivity of aluminum and the parasitic capacitance between neighboring metal regions. Therefore, in modern integrated circuits, highly conductive metals, such as copper and alloys thereof, are used to accommodate the high current densities encountered during the operation of the devices, while the parasitic capacitance may be reduced by using low-k dielectric materials, which are to be understood as dielectrics having a dielectric constant of 3.0 or less.

In an advanced stage of the manufacture of integrated circuits, it is usually necessary to package a chip and provide leads and terminals for connecting the chip circuitry with the periphery. In some packaging techniques, chips, chip packages or other appropriate units may be connected by means of solder balls, formed from so-called solder bumps, that are formed on a corresponding layer of at least one of the units, for instance on a dielectric passivation layer of the microelectronic chip. In order to connect the microelectronic chip with the corresponding carrier, the surfaces of two respective units to be connected, i.e., the microelectronic chip comprising, for instance, a plurality of integrated circuits, and a corresponding package, have formed thereon adequate pad arrangements to electrically connect the two units after reflowing the solder bumps provided at least on one of the units, for instance on the microelectronic chip. In other techniques, solder bumps may have to be formed that are to be connected to corresponding wires, or the solder bumps may be brought into contact with corresponding pad areas of another substrate acting as a heat sink. Consequently, it may be necessary to form a large number of solder bumps that may be distributed over the entire chip area, thereby providing, for example, the I/O (input/output) capability as well as the desired low-capacitance arrangement required for high frequency applications of modern microelectronic chips that usually include complex circuitry, such as micro-processors, storage circuits and the like, and/or include a plurality of integrated circuits forming a complete complex circuit system.

Another approach for connecting chips with a package includes wire bonding techniques, which have been successfully developed over many decades on the basis of aluminum and are still well established and represent the dominant technology for connecting the vast majority of semiconductor chips to a carrier substrate, wherein usually aluminum-based bond pads are provided, which are contacted by an appropriate wire made of aluminum, copper, gold and the like. During the wire bonding process, the bond wire is then at end brought into contact with the bond pad. Upon applying pressure, elevated temperature and ultrasonic energy, the wire, which may have formed thereon a ball, if required, is welded to the bond pad so as to form an intermetallic connection. Thereafter, the other end of the bond wire may be bonded to a lead pin of the package, in which the semiconductor chip is mechanically fixed during the bond process. However, many advanced semiconductor devices may have a copper-based metallization structure in view of device performance, integration density and process compatibility in facilities fabricating a wide variety of different products, wherein, however, the connection to the carrier substrate or the package is to be established by wire bonding due to less demanding I/O capabilities as compared to, for instance, CPUs and other highly complex ICs, and the economic advantages of the wire bonding techniques over complex bump-based techniques. For example, sophisticated memory devices may require very complex high performance metallization systems, while the I/O capacity may readily be achieved on the basis of wire bonding. In a production environment, however, the wire bonding on copper bond pads is very difficult to achieve due to an inhomogeneous self-oxidization of the copper surface in combination with extensive corrosion, which may result in highly non-reliable bond connections. That is, the bond pads and the bond wires connected thereto may suffer from pronounced corrosion, in particular when exposed to sophisticated environmental conditions, as may occur during normal operation and in particular during test periods performed at elevated temperatures. As an example, accelerated reliability tests are typically performed at a temperature of 300° C. and higher, thereby contributing to a premature failure of the bond structures.

For this reason, a different terminal metal compared to copper, such as an aluminum metal layer, may be used in an advanced metallization structure based on copper, possibly in combination with low-k dielectrics, which may result in a more complex manufacturing process, since respective process tools and processes for forming and patterning aluminum layers have to be provided in the production line. For example, for modem CPUs, in which both wire bonding and direct solder contact regimes using bump structures are to be employed, for instance, for packaging respective test structures for monitoring the overall complex process flow of CPUs, significant additional efforts may have to be made during the formation of the bump structure for actual die regions including the CPUs and the wire bonding pads for respective test structures, as will be described in more detail with reference to FIGS. 1a-1c.

FIG. 1a schematically illustrates a cross-sectional view of a conventional semiconductor device 100 in an advanced manufacturing stage. The semiconductor device 100 comprises a substrate 101, which may have formed therein circuit elements and other microstructural elements that, for convenience, are not shown in FIG. 1a. The device 100 comprises one or more metallization layers including copper-based metal lines and vias, wherein, for convenience, the very last metallization layer 110 is shown, which may comprise a dielectric material 111 having formed therein a copper-containing metal region 112. That is, the metal region 112 may be formed of copper or a copper alloy, possibly in combination with respective barrier materials (not shown) to suppress any interaction between the dielectric material 111 and the copper material in the region 112. The metal region 112 may be electrically connected to any circuit elements representing an integrated circuit in accordance with a specific circuit arrangement, or the metal region 112 may represent a contact area connecting to device features representing a test structure so as to characterize specific device properties, such as electromigration performance, reliability of gate dielectrics and the like, as previously explained. The semiconductor device 100 further comprises a passivation layer stack 120, which may comprise a plurality of individual layers, indicated as dielectric layers 121, 122 and 123. For example, the dielectric layer 121 may be in direct contact with the metal region 112 and may be comprised of any appropriate material so as to act a as a cap layer for confining the copper material in the region 112. For example, the dielectric layer 121 may be comprised of silicon nitride, silicon carbide, nitrogen-containing silicon carbide and the like. Moreover, the layers 122 and 123 may be provided in any appropriate material composition so as to comply with the further processing of the device 100 and act as an appropriate passivation layer to insure integrity of any underlying components. For example, silicon dioxide, silicon oxynitride, silicon nitride and the like may be used for the dielectric layer 122, and also for the layer 123, depending on the overall process and device requirements. As shown, the passivation layer 120 may expose an appropriate portion of the metal region 112 as may be required for providing an appropriate bond area for receiving a bond wire 130. However, due to the highly reactive nature of the exposed surface portion of the metal region 112, corresponding surface contaminants, such as corrosive areas and the like 112A, may be created in a more or less pronounced manner, in particular during sophisticated environmental conditions 150, such as elevated temperatures which may occur during operation of the device 100 and the testing, such as accelerated reliability tests. Hence, a premature contact failure may be observed.

The semiconductor device 100 as shown in FIG. 1a may be formed on the basis of the following processes. Initially, the substrate 101 and any circuit elements contained therein may be manufactured on the basis of well-established process techniques, wherein, in sophisticated applications, circuit elements having critical dimensions on the order of magnitude of approximately 50 nm and less may be formed, followed by application of the one or more metallization layers 110 including copper-based metal lines and vias, wherein, typically, low-k dielectric materials are used for at least some of the dielectric materials in the metallization system of the device 100. The process sequence for forming the metallization layer 110 representing the very last metallization level of the device 110 typically includes the deposition of the dielectric material 111 and the patterning thereof, followed by filling in the copper-containing material, for instance on the basis of electrochemical deposition techniques, wherein the deposition of appropriate barrier materials, such as tantalum, tantalum nitride and the like, may precede the deposition of the copper material. After removal of any excess material, the dielectric layer 121 may be formed, for instance by appropriate deposition techniques, thereby confining the copper-based materials, such as the metal region 112. Next, the further dielectric layers 122 and 123 of the passivation layer stack 120 may be formed on the layer 121 on the basis of any appropriate deposition technique, such as plasma enhanced chemical vapor deposition (CVD) and the like. Thereafter, a photolithography process is performed to provide a resist mask (not shown) having a shape and dimension that substantially determines the actual bond area for connecting the bond wire 130 with the exposed portion of the metal region 112. Subsequently, the dielectric layer stack 120 may be patterned on the basis of the previously defined resist mask, which may finally be removed by well-established process techniques. Thereafter, the device 100 may be separated by dicing the substrate 101 and thereafter the separated device 100 may be attached to a carrier substrate or package (not shown) and the bond wire 130 may be bonded to the metal region 112 and to a bond pad (not shown) of the carrier substrate. Due to the creation of the contaminants 112A during the operation and/or testing of the device, a reliable intermetallic connection between the bond wire 130 and the surface of the metal region 112 may be difficult to be achieved and, therefore, in conventional approaches, the device 100 may receive an aluminum-based terminal metal layer to allow the application of well-approved wire bonding techniques on the basis of aluminum, as will be described with reference to FIGS. 1b-1c.

FIG. 1b schematically illustrates the conventional semiconductor device 100 in a further advanced manufacturing stage, in which an aluminum layer 131 may be formed above the exposed portion of the metal region 112. Furthermore, as shown, a barrier/adhesion layer 132 may be positioned between the aluminum layer 131 and the metal region 112 and the respective part of the dielectric layer stack 120. The barrier/adhesion layer 132 may, for instance, be comprised of tantalum, tantalum nitride, titanium, titanium nitride or other similar metals and compounds thereof as are typically used in combination with copper metallization systems in order to effectively reduce copper diffusion and enhanced adhesion of the aluminum layer 131. Typically, the device 100 as shown in FIG. 1b may be formed by first depositing the barrier/adhesion layer 132, for instance on the basis of sputter deposition techniques, followed by the deposition of the aluminum layer 131, for instance by sputter deposition, chemical vapor deposition and the like. Next, a lithography process is performed to create a resist mask (not shown), which may be used as an etch mask during a reactive etch process, which may be performed, for instance, on the basis of a complex chlorine based etch chemistry in order to obtain the patterned aluminum layer 131, as shown in FIG. 1b. Furthermore, the respective etch process may also include a separate etch step for etching through the barrier/adhesion layer 132, followed by a wet chemical process for removing any corrosive etch residues generated during the complex aluminum etch step.

FIG. 1c schematically illustrates the semiconductor device 100 in a further advanced manufacturing stage, in which the bond wire 130 may be bonded to the aluminum layer 131 by well-established process techniques, in which an end of the bond wire 130 may be attached to the exposed surface of the aluminum layer 131 while also applying heat and/or ultrasonic energy and pressure, thereby obtaining an intermetallic connection between a portion of the aluminum layer 131 and the bond wire 130.

Consequently, in the conventional approach described above, efficient wire bond techniques may be used on the basis of the aluminum layer 131, thereby, however, requiring a complex process sequence for depositing and patterning the barrier/adhesion layer 132 and the aluminum layer 131. Consequently, in a complex manufacturing environment, respective resources for depositing and patterning the aluminum layer 131 in combination with the barrier/adhesion layer 132 may have to be provided in addition to equipment and materials required for the formation of a complex copper-based metallization system, thereby contributing to increased cycle times and thus production costs.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to techniques and semiconductor devices in which wire bonding in copper-based metallization structures may be accomplished without using aluminum-based techniques by passivating an exposed copper-containing surface after the wire bonding process. For this purpose, an appropriate dielectric material may be formed at least on the metal region having attached thereto the bond wire, thereby encapsulating and thus passivating the exposed surface of the metal region, which may thus be protected with respect to the formation of corrosion and the like, in particular during elevated temperatures, as may occur during operation of the device and in particular during accelerated reliability tests and the like. The encapsulation of at least the exposed metal region of the final metallization layer may be accomplished on the basis of a plurality of dielectric materials, such as polymer materials and the like, which may be applied in a low viscous state and may be hardened on the basis of radiation, heat and the like. For this purpose, a plurality of dielectric materials are well known in the art of printed wiring board techniques, which may also provide a high degree of integrity with respect to moisture, oxygen and the like, thereby providing a high degree of integrity of copper-containing bond areas without requiring additional measures, such as chip internal passivation layers and the like. Furthermore, the encapsulating of the sensitive copper-containing surface areas may be based on a coasting process that may readily be implemented into conventional packaging techniques without unduly contributing to overall process complexity, while, in some illustrative aspects disclosed herein, the configuration of the package and thus of the packaging process may be simplified by replacing a package cover by the fill material. In other illustrative aspects disclosed herein, the fill material may additionally be adapted so as to enhance the overall thermal characteristics of the packaged semiconductor device, for instance by appropriately adapting the coefficient of the thermal expansion and/or the thermal conductivity of the fill material in order to reduce thermal stress and/or a temperature gradient between the semiconductor chip and the package. Thus, during the process of forming the semiconductor chip, complex metallization systems may be provided on the basis of highly conductive metals, such as copper, silver and the like without requiring specific materials and process techniques for a dedicated final bond material, such as aluminum, thereby contributing to significantly reduced efforts with respect to equipment and cycle time of sophisticated integrated circuits, while nevertheless providing an efficient packaging process on the basis of wire bond techniques without jeopardizing the overall integrity of the wire bond connection.

One illustrative method disclosed herein comprises providing a final metallization layer formed above a substrate of a semiconductor device, wherein the final metallization layer comprises a contact region having an exposed copper-containing surface for receiving a bond wire. The method further comprises bonding the bond wire to the exposed copper-containing surface and encapsulating the exposed copper-containing surface and at least a portion of the bond wire connected to the exposed copper-containing surface.

A further illustrative method disclosed herein comprises forming a metallization system of a semiconductor device on the basis of a single highly conductive metal, wherein the metallization system comprises a final metallization layer comprising a plurality of metal regions for connecting to bond wires. The method additionally comprises attaching the semiconductor device to a carrier substrate that comprises a plurality of bond pads connecting to lead terminals. Furthermore, the method comprises bonding a bond wire to each of the plurality of metal regions and each of the plurality of bond pads and passivating at least the plurality of metal regions with a dielectric material.

An illustrative integrated circuit disclosed herein comprises a chip comprising a substrate and a metallization system that comprises a final metallization layer having copper-containing metal regions and bond wires attached with one end to the copper-containing metal regions. The integrated circuit further comprises a carrier substrate comprising a plurality of bond pads, wherein the bond wires are attached with another end thereof to the bond pads. Finally, the integrated circuit comprises a fill material encapsulating the metal region and at least a portion of the bond wires connected to the metal regions.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device including an exposed copper surface for wire bond connection and the resulting surface contamination, which may occur during operation and elevated temperature testing;

FIGS. 1b-1c schematically illustrate cross-sectional views of a conventional semiconductor device during various manufacturing stages in forming a wire bond structure on the basis of a copper-containing metallization system and a terminal aluminum layer, according to conventional strategies;

FIG. 2a schematically illustrates a portion of an integrated circuit comprising a metallization system with a final metallization layer based on a highly conductive metal, such as copper, silver and the like, in a wire bond structure that is encapsulated by a dielectric fill material, according to illustrated embodiments; and

FIGS. 2b-2c schematically illustrate cross-sectional views of an integrated circuit, i.e., of a chip and a corresponding package, wherein bond wires are connected to copper-containing surface areas of bond pads, the integrity of which is maintained by means of the dielectric fill material, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The subject matter disclosed herein relates to techniques and semiconductor devices in which wire bonding structures may be formed on the basis of a substantially aluminum-free metallization system, wherein a reliable intermetallic connection between the bond wire and a copper-containing surface may be accomplished by appropriately encapsulating the copper-containing surface after the wire bond process. For this purpose, the semiconductor chip may be formed on the basis of process techniques in which well-established materials as may typically be used during the formation of advanced semiconductor devices may also be employed during the fabrication of the wire bond structure, thereby reducing effort in terms of equipment and process time compared to conventional strategies, in which an aluminum terminal metal layer is used. In some illustrative embodiments disclosed herein, the corresponding manufacturing process for forming the final metallization layer may be based on techniques that do not require any specific passivation of the exposed copper surface of the bond pads of the final metallization layer. However, after dicing the substrate and electrically connecting a semiconductor chip to a corresponding lead frame, carrier substrate or package by means of wire bonding, at least the exposed copper surfaces of the bond pads of the semi-conductor chip may be passivated by encapsulating respective portions of the semiconductor device on the basis of an appropriate dielectric material. To this end, well-established cast materials may be used, such as polymers, materials on the basis of resins and the like, wherein, additionally, in some embodiments, the thermal characteristics of these fill materials may be adapted to enhance the overall thermal characteristics of the finalized integrated circuit. For instance, in addition to diffusion blocking capabilities with respect to reactive components, such as moisture, oxygen and the like, which may conventionally result in premature contact failures of exposed copper-containing surfaces, the fill material may also provide enhanced thermal conductivity compared to conventional packages and/or may reduce mechanical stress that may be induced by a significant mismatch of coefficients of thermal expansion between the package and the actual semiconductor chip. For instance, heat dissipation of the integrated circuit may be efficiently increased by encapsulating the semiconductor chip or at least the metallization system thereof by the fill material having enhanced thermal conductivity, which may therefore result in a more efficient heat dissipation compared to conventional packages without the fill material. In other cases, undue thermal stress which may occur at the wire bond connections on the metallization layer may be reduced by appropriately adapting the coefficients of thermal expansion of the fill material with respect to the semiconductor chip, so that a mismatch between the semiconductor chip and the package material may not directly affect the wire bond structure but may occur at less critical areas, such as an interface between the fill material and the package material. Furthermore, in some illustrative embodiments, the attaching of the semiconductor chip to the carrier substrate or the package may be accomplished during the process for encapsulating the exposed critical surface area of the semiconductor chip, for instance, by first forming a layer of the fill material for attaching the semiconductor chip and providing additional fill material after the wire bond process. In this manner, increased utilization of respective tools for encapsulating the wire bond structure may be accomplished while additionally increased flexibility may be provided with respect to adjusting the overall thermal characteristics of the corresponding packaged integrated circuit.

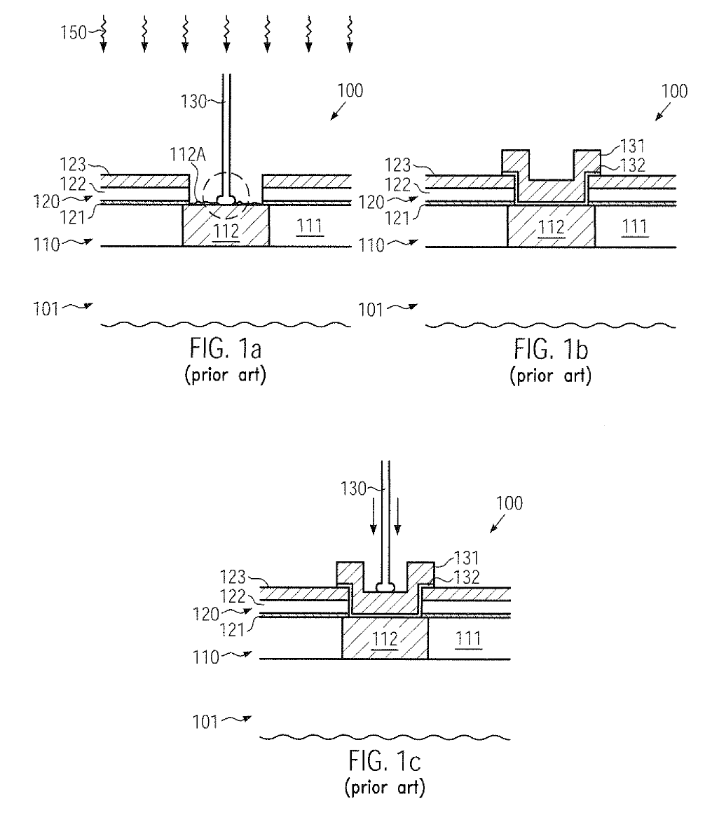

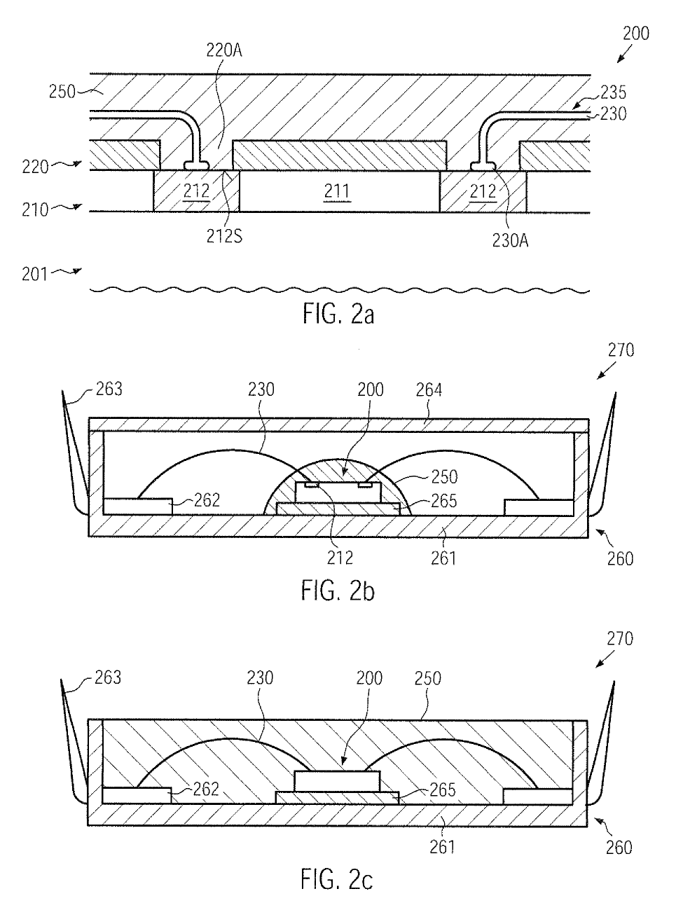

With reference to FIGS. 2a-2c, further illustrative embodiments will now be described in more detail, wherein references may also be made to the device 100 according to FIG. 1a and the corresponding manufacturing techniques, if appropriate.

FIG. 2a schematically illustrates a cross-sectional view of a semiconductor device 200 which may represent an advanced device having incorporated therein a complex metallization system based on highly conductive metals, such as copper, silver and the like, wherein wire bond contact structures may provide the connection to corresponding bond pads of the periphery, such as a carrier substrate, a package, a lead frame and the like, while avoiding an aluminum-based terminal metal layer, as explained before. For instance, the semiconductor device 200 may represent a portion of a chip comprising an appropriate electronic circuit in the form of a memory device, such as static RAM circuits, non-volatile devices, for instance in the form of flash memory devices, and the like. As previously explained, many memory devices may represent semiconductor devices in which high performance with respect to signal propagation delay, packing density and the like may be required, while only moderate I/O capabilities are required to communicate with other electronic devices. In other cases, the semiconductor device 200 may represent an integrated circuit including a test structure for complex CPUs, which may frequently be formed together with CPUs so as to enable efficient process control, wherein wire bond structures may be appropriate for meeting the I/O capabilities of the corresponding test structures. The integrated circuit or device 200 may comprise one or more device levels and one or more metallization levels, which, for convenience, are commonly referred to as 201. It should be appreciated that the one or more device levels and the one or more metallization levels may have a configuration as previously explained with reference to the semiconductor device 100 described with reference to FIG. 1a and also with reference to FIGS. 1b-1c, except for the final metallization level. Thus, a further detailed description of corresponding device features and manufacturing techniques may be omitted here. Additionally, a final or last metallization level 210 may comprise a plurality of metal regions 212, a portion of which may act as contact areas for a wire bond structure 235. The metal regions 212 may be embedded in a dielectric material 211, above which may be formed a passivation layer stack 220. It should be appreciated that the stack 220 may be comprised of a single material layer or may include a plurality of individual material layers, depending on the overall requirements, as is, for instance, also described with reference to the semiconductor device 100. The contact structure 235 may include a bond wire 230 having an end portion 230A which is in direct contact with a surface portion 212S of the metal regions 212, thereby forming an intermetallic connection. Furthermore, the contact portion 230A and remaining portion of the surface 212S exposed by the dielectric layer stack 220 may be in contact with a fill material 250 which may encapsulate and thus confine the metal regions 212. In the embodiment shown, the fill material 250 may confine the metallization layer 210, the dielectric layer stack 220 and the wire bond structure 235, which in turn may be connected to respective contact leads for bond pads or pins (not shown) of a lead frame, a carrier substrate or a package, depending on the overall configuration of the integrated circuit 200. The fill material 250 may represent any appropriate material that may be supplied in a low viscous state so as to adapt to the specific surface topography of the stack 220 in order to reliably cover exposed surface portions, such as the surface portions 212S. For instance, a plurality of polymer materials may be used, which may also provide the desired integrity of the exposed surface portions 212S. For instance, a plurality of resin materials may be available, which may be used for appropriately “coasting” at least a portion of the final metallization layer 210 and the passivating dielectric layer stack 220 in order to confine the sensitive metal regions 212. It should be appreciated that a plurality of material compositions are well established in the art of printed wiring board techniques, which may be hardened within short time intervals and which may provide the desired mechanical and chemical stability, while at the same time exhibiting temperature stability up to several hundred degrees Celsius, for instance up to 350° C. and higher, thereby providing the desired confinement of the metal regions 212 for typical thermal conditions encountered during accelerated reliability tests of integrated circuits. Furthermore, in some illustrative embodiments, the fill material 250 may have a moderately high thermal conductivity, which may, for instance, be adjusted by incorporating respective substances, such as metal particles and the like, which may even be used for locally adapting the overall thermal conductivity. Thus, the fill material 250 may also provide an efficient heat dissipation from the final metallization layer 210, since, for instance, efficient thermal coupling to the bond wires 230 may be accomplished by embedding at least a significant portion of the wires 230 into the fill material 250. Furthermore, as will be described later on in more detail, the material 250 may be provided such that contact to a carrier substrate or package may also be achieved, thereby increasing the surface available for an efficient heat transfer from the device 200 to a corresponding package material. In still other illustrative embodiments, the material 250 may be selected with respect to its coefficient of thermal expansion so as to reduce any thermally induced mechanical stress, in particular for the wire bond structure 235. For instance, the coefficient of thermal expansion of the material 250, at least in the vicinity of the metallization level 210 and the layer stack 220, may be selected so as to be close to the coefficient for these components, thereby substantially avoiding significant mechanical stress immediately at the contact portion 230A, even if the fill material 250 may connect to a package material having a significantly different coefficient of thermal expansion, as is typically the case for organic package materials. In this case, the corresponding mechanical stress may have to act across the fill material 250, which may thus represent a buffer layer, thereby significantly reducing the corresponding forces on the bond wire 230, which may also contribute to the overall enhanced reliability of the wire bond structure 235.

The semiconductor device 200 may be formed in accordance with process techniques, as previously described with reference to the device 100, wherein, in particular, the wire bond contact structure 235 may be formed on the basis of a substantially aluminum-free technique. That is, after dicing the substrate 201 so as to separate individual semiconductor die or chips, the bond wires 230 may be brought into contact with the metal regions 212 without providing a terminal aluminum layer on the metal regions 212 and without providing any additional protective materials, thereby obtaining a highly efficient overall manufacturing flow. Thus, complex metallization systems on the basis of copper, silver and the like may be used for the device 200 without requiring additional resources for depositing and patterning aluminum-based terminal metal layers and without requiring an additional process step for passivating the exposed surface 212S prior to performing the wire bond process.

FIG. 2b schematically illustrates an integrated circuit 270 in a packaged state. As illustrated, the integrated circuit 270 may comprise the semiconductor device 200 in the form of a single chip or any other chip configuration, wherein at least one final metallization layer may be provided to enable a wire bond connection. For convenience, it may be assumed that the semiconductor device 200 may have a similar configuration as is described with reference to the semiconductor device 200 of FIG. 2a or the device 100 as previously described with reference to FIG. 1a. Furthermore, the integrated circuit 270 may comprise a carrier substrate or any other appropriate system for providing bond pads to connect to the chip 200, for instance in the form of a package 260, as illustrated in FIG. 2b. The package 260 may comprise a base 261 in and on which a plurality of bond pads 262 may be provided, which may in turn be electrically connected to leads 263, for instance in the form of pins or any other contact elements so as to connect to printed wiring boards and the like. Furthermore, a cover 264 may seal the package 260. Additionally, in the embodiment shown, the fill material 250 may encapsulate at least the exposed metal regions 212 and a portion of the corresponding bond wires 230, which may connect to the corresponding bond pads 262. In the embodiment shown, the fill material 250 may substantially encapsulate the entire semi-conductor chip 200, thereby providing enhanced overall integrity of the chip 200 with respect to humidity or oxidation of sensitive metal regions, such as copper regions provided in the metallization system of the chip 200, as previously explained. In other illustrative embodiments (not shown), the fill material 250 may be locally restricted to the final metallization layer 210, as illustrated with respect to FIG. 2a, while, in other cases, the material 250 may even be locally restricted to the individual metal regions 212, if desired.

The integrated circuit 270 as shown in FIG. 2b may be formed on the basis of the following processes. After attaching the chip 200 to the package 260, i.e., the base 261, which may, for instance, be accomplished by providing an appropriate adhesive 265 or any other intermediate material, the bond wires 230 may be connected to the metal regions 212 and the bond pads 262 on the basis of well-established automated wire bond techniques. Depending on the overall characteristics of the bond wires 230 and the corresponding metal regions 212 and 262, heat, ultrasonic energy, pressure and the like may be applied to obtain the desired intermetallic connection. In some illustrative embodiments, after bonding one or more bond wires 230, an intermediate “passivation” step may be performed to provide the material 250 locally at the one or more metal regions 212 which may have previously received the bond wires 230. Thereafter, the wire bond process may be continued, possibly followed by a further intermediate locally restricted application of the fill material 250. In other illustrative embodiments, after establishing all required wire bond connections, the fill material 250 may be applied, for instance, by any appropriate applicator so as to encapsulate relevant portions of the device 200 or by completely encapsulating the device 200. Thereafter, the material 250 may be hardened, which may be accomplished on the basis of elevated temperatures, appropriate radiation, such as UV radiation, and the like. For instance, a plurality of materials are well established in the art, which may be hardened within several minutes, thereby providing an immediate reliable confinement of the sensitive metal regions 212. In other illustrative embodiments, the semiconductor chip 200 may be attached to the base 261 by applying a portion of the material 250, mechanically attaching the chip 200 and curing the material 250 and subsequently performing the wire bond process as described above. Thereafter, the remaining portion of the chip 200 may be encapsulated by further providing material 250, as described above. Hence, the thermal behavior of the chip 200 in combination with the encapsulating material 250 may be appropriately selected, for instance, with respect to thermal conductivity, coefficient of thermal expansion and the like, to obtain enhanced performance compared to conventional packages, in which the fill material 250 is not provided. After applying the material 250 and after or prior to hardening the same, the cover 264 may be attached to the base 261 so as to seal the package 260.

FIG. 2c schematically illustrates the integrated circuit 270 according to further illustrative embodiments in which the fill material 250 may substantially completely fill the interior of the package 260. Thus, overall enhanced mechanical integrity of the integrated circuit 270 may be accomplished, for instance with respect to the bond wires 230, the inter-metallic connection of the bond wires 230 with the bond pads 262 and the adhesion of the integrated circuit chip 200 to the package 260. Furthermore, the chip 200 may have an enhanced thermal coupling to the package 260 via the fill material 250, thereby enhancing the heat dissipation capability of the integrated circuit 270. Thus, in some cases, respective heat sinks may be omitted, thereby contributing to less material consumption and a simplified overall configuration of the package 260. Furthermore, as previously described, the thermal characteristics of the fill material 250 may be appropriately adapted, for instance, with respect to thermal conductivity, coefficient of thermal expansion and the like, to provide the desired overall thermal behavior of the integrated circuit 270. That is, by using a fill material 250 having a thermal conductivity that is comparable to the thermal conductivity of the chip 200, highly efficient heat transfer to the outside of the package 260 may be accomplished, on which external heat sinks may be provided or wherein the increased surface area may provide a sufficient cooling effect. Furthermore, in some illustrative embodiments, the fill material 250 may replace the cover 264 (FIG. 2b), thereby simplifying the overall manufacturing flow for packaging the chip 200. Hence, after hardening the material 250, the package 260 may be sealed by the material 250, which may also provide the enhanced integrity of the metal regions 212, while also providing enhanced integrity of the interior of the package 260.

As a result, the present disclosure provides semiconductor devices and integrated circuits and corresponding manufacturing techniques in which reduced process complexity may be accomplished during the formation of wire bond structures by eliminating aluminum-based deposition and patterning sequences. For this purpose, reactive metal surfaces, such as copper-containing surfaces, may be encapsulated after the wire bond process, thereby providing enhanced integrity of the sensitive metal regions without requiring sophisticated process flows for passivating the exposed sensitive metal surfaces prior to and during the wire bond process. Hence, sophisticated integrated circuits may be formed with reduced costs and reduced cycle time with respect to the metallization system, while the fill material provides enhanced stability during elevated temperatures which may occur during operation and/or during accelerated reliability tests and the like, for instance, test ICs of complex integrated circuits, memory devices, such as flash memories, and the like.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
providing a final metallization layer formed above a substrate of a semiconductor die, said final metallization layer comprising a contact region having an exposed copper-containing surface for receiving a bond wire;
bonding said bond wire to said exposed copper-containing surface; and
encapsulating said exposed copper-containing surface and at least a portion of said bond wire connected to said exposed copper-containing surface.

2. The method of claim 1, wherein encapsulating said exposed copper-containing surface comprises positioning said semiconductor die within a package and filling said package at least partially with a dielectric material.

3. The method of claim 1, wherein encapsulating said exposed copper-containing surface comprises wetting at least said copper-containing surface with a dielectric material in a low-viscous state.

4. The method of claim 3, further comprising curing said dielectric material by applying at least one of heat and ultra-violet radiation.

5. The method of claim 1, wherein providing said final metallization layer comprises forming said final metallization layer on the basis of copper material without using aluminum-based materials.

6. The method of claim 1, further comprising adjusting a coefficient of thermal expansion of a dielectric material used for encapsulating so as to reduce thermal stress on said final metallization layer.

7. The method of claim 6, wherein said coefficient of thermal expansion of at least a portion of said dielectric material is adapted so as to substantially correspond to an average coefficient of thermal expansion of said substrate.

8. The method of claim 7, wherein said coefficient of thermal expansion of said at least a portion of said dielectric material substantially coincides with the coefficient of thermal expansion of said substrate.

9. The method of claim 1, wherein encapsulating said exposed copper-containing surface and at least a portion of said bond wire connected to said exposed copper-containing surface comprises applying a polymer material.

10. The method of claim 2, wherein said dielectric material substantially completely fills an interior of said package.

11. The method of claim 1, further comprising bonding a second lead wire to a second exposed copper-containing surface and encapsulating said second exposed copper-containing surface and at least a portion of said second bond wire connected to said second exposed copper-containing surface after encapsulating said copper-containing surface.

12. The method of claim 1, wherein said final metallization layer is a part of a memory device.

13. A method, comprising:
forming a metallization system of a semiconductor device on the basis of a single highly conductive metal, said metallization system comprising a final metallization layer comprising a plurality of metal regions for connecting to bond wires;
attaching said semiconductor device to a carrier substrate comprising a plurality of bond pads connecting to lead terminals;
bonding a bond wire to each of said plurality of metal regions and each of said plurality of bond pads; and
passivating at least said plurality of metal regions with a dielectric material.

14. The method of claim 13, wherein passivating at least said plurality of metal regions comprises encapsulating said metal regions and at least a portion of each of said bond wires by said dielectric material.

15. The method of claim 14, further comprising encapsulating said bond pads.

16. The method of claim 13, wherein said carrier substrate is provided as a package and wherein passivating said metal regions comprises filling at least a portion of an interior of said package with said dielectric material.

17. The method of claim 16, wherein said interior of said package is substantially completely filled with said dielectric material.

18. The method of claim 17, wherein said dielectric material is used for sealing said package.

19. An integrated circuit, comprising:
a chip comprising a substrate and a metallization system, said metallization system comprising a final metallization layer having copper-containing metal regions and bond wires attached with one end to said copper-containing metal regions;
a carrier substrate comprising a plurality of bond pads, said bond wires being attached with another end thereof to said bond pads; and
a fill material encapsulating said metal regions and at least a portion of said bond wires connected to said metal regions.

20. The integrated circuit of claim 19, wherein said fill material encapsulates said bond pads.

21. The integrated circuit of claim 19, wherein said carrier substrate is a package.

22. The integrated circuit of claim 21, wherein said fill material substantially completely fills an interior of said package.

23. The integrated circuit of claim 19, wherein said fill material comprises a polymer material.

24. The integrated circuit of claim 19, wherein said integrated circuit is a memory device.

25. The integrated circuit of claim 22, wherein said fill material acts as a cover of said package.
